(19) United States
(12) Patent Application Publication
(10) Pub. No.: US 2023/0252273 A1
(43) Pub. Date: Aug. 10, 2023

(54) SYSTEMS AND METHODS FOR ENCODING/DECODING A DEEP NEURAL NETWORK

(71) Applicant: INTERDIGITAL VC HOLDINGS FRANCE, SAS, Cesson Sevigne (FR)

(72) Inventors: Fabien Racape, San Francisco, CA (US); Shahab Hamidi-Rad, Sunnyvale, CA (US); Swayambhoo Jain, Milpitas, CA (US)

(73) Assignee: INTERDIGITAL VC HOLDINGS FRANCE, SAS, Cesson Sevigne (FR)

(21) Appl. No.: 18/010,233

(22) PCT Filed: Jun. 9, 2021
(86) PCT No.: PCT/EP2021/065522

§ 371 Date: Dec. 14, 2022

Related U.S. Application Data
(60) Provisional application No. 63/040,048, filed on Jun. 17, 2020.
(60) Provisional application No. 63/050,052, filed on Jul. 9, 2020.

(51) Int. Cl. G06N 3/0495

(52) U.S. Cl. CPC G06N 3/0495

(57) ABSTRACT

The disclosure relates to a method comprising, responsive to a determination that at least one first tensor of at least one layer of at least one Deep Neural Network is decomposed into a second tensor and a third tensor whose parameters are encoded in a bitstream, decoding from the bitstream a size of at least one of the second tensor and the third tensor, and decoding the at least one of the second tensor and the third tensor from the bitstream based on the decoded size. Corresponding apparatus, encoding method, signal; bitstream, storage media and encoder and/or decoder devices are also provided.

The domain technical field of the one or more embodiments of the present disclosure is related to the technical domain of data processing, like for data compression and/or decompression. For instance, at least some embodiments relate to data compression/decompression involving large volume of data, like compression and/or decompression of at least a part of an audio and/or video stream, or like compression and/or decompression of data in link with Deep Learning techniques, like at least some parameters of a Deep Neural Network (DNN).

At least some embodiments relate to improving compression efficiency compared to existing video compression systems such as HEVC (HEVC refers to High Efficiency Video Coding, also known as H.265 and MPEG-H Part 2 described in “ITU-T H.265 Telecommunication standardization sector of ITU (October 2014), series H: audiovisual and multimedia systems, infrastructure of audiovisual services—coding of moving video, High efficiency video coding, Recommendation ITU-T H.265”), or compared to under development video compression systems such VVC (Versatile Video Coding, a new standard being developed by JVET, the Joint Video Experts Team).

To achieve high compression efficiency, image and video coding schemes usually employ prediction, including spatial and/or motion vector prediction, and transforms to leverage spatial and temporal redundancy in the video content. Generally, intra or inter prediction is used to exploit the intra or inter frame correlation, then the differences between the original image and the predicted image, often denoted as prediction errors or prediction residuals, are transformed, quantized, and entropy coded. To reconstruct the video, the compressed data are decoded by inverse processes corresponding to the entropy coding, quantization, transform, and prediction.

At least some embodiments relate to improving compression efficiency compared to existing systems for compression a Deep Neural Network (DNN). such as some compression standard or draft standard like the current upcoming standard ISO/MPEG7 of neural networks for multimedia content description and analysis current developed by the International Organization for Standardization.

Generally, in an encoding process, parameters of a DNN are quantized and entropy coded to obtain compressed data. To reconstruct data, the compressed data are decoded, the decoding processes including entropy decoding and inverse quantization.

### SUMMARY OF THE INVENTION

The present principles enable at least one of disadvantages of some known compression and/or decompression methods to be resolved by proposing a method and an apparatus for encoding or decoding data in at least one bitstream, data being one or more parameters of at least one tensor of at least one layer or sub-layer of at least one Deep Neural Network. It is to be pointed out that tensor of parameters associated to a layer can include weights and/or biases, even if sometimes simply called “weights” in the following for concision purpose.

According to an embodiment, a method for decoding at least one first tensor of at least one layer of at least one Deep Neural Network is provided. Such a method comprises responsive to a determination that at least one first tensor is decomposed into a second tensor and a third tensor whose parameters are encoded in a bitstream, decoding from the bitstream a size of at least one of the second tensor and the third tensor, and decoding the at least one of the second tensor and the third tensor from the bitstream based on the decoded size. According to another embodiment, an apparatus for decoding at least one first tensor of at least one layer of at least one Deep Neural Network is provided. The apparatus comprises one or more processors configured to determine that at least one first tensor of at least one layer of at least one Deep Neural Network is decomposed into a second tensor and a third tensor whose parameters are encoded in a bitstream, decode from the bitstream a size of at least one of the second tensor and the third tensor, decode the at least one of the second tensor and the third tensor from the bitstream based on the decoded size.

According to another embodiment, a method comprising encoding data representative of at least one first tensor of at least one layer of the Deep Neural Network in a bitstream is provided. The method comprises responsive to a determination that the at least one first tensor is decomposed into a second tensor and a third tensor, encoding a size of at least one of the second tensor and the third tensor, encoding parameters representative of the at least one of the second tensor and the third tensor.

According to another embodiment, an apparatus for encoding data representative of at least one first tensor of at least one layer of the Deep Neural Network in a bitstream is provided, wherein the apparatus comprises one or more processors, wherein the one or more processors are configured for determining that the at least one first tensor is decomposed into a second tensor and a third tensor, responsive to the determination, encoding a size of at least one of the second tensor and the third tensor, encoding the at least one of the second tensor and the third tensor.

One or more embodiments also provide a computer program comprising instructions which when executed by one or more processors cause the one or more processors to perform the encoding method or decoding method according to any of the embodiments described above. One or more of the present embodiments also provide a computer readable storage medium having stored thereon instructions for encoding or decoding data according to the methods described above. One or more embodiments also provide a computer readable storage medium having stored thereon a bitstream generated according to the methods described above. One or more embodiments also provide a method and apparatus for transmitting or receiving the bitstream generated according to the methods described above.

According to another general aspect of at least one embodiment, there is provided a device comprising an apparatus according to any one of the decoding embodiments; and at least one of (i) an antenna configured to receive a signal, the signal including the input data, (ii) a band limiter configured to limit the received signal to a band of frequencies that includes the input data, or (iii) a display configured to display an output representative of a video block.

While not explicitly described, the devices of the present disclosure can be adapted to perform the methods of the present disclosure in any of theirs embodiments.

While not explicitly described, the present embodiments related to the methods or to the corresponding signal, devices, and computer readable storage media can be employed in any combination or sub-combination.

### BRIEF DESCRIPTION OF THE DRAWINGS

FIG. 1 shows a generic, standard encoding scheme.

FIG. 2 shows a generic, standard decoding scheme.

FIG. 3 shows a typical processor arrangement in which the described embodiments may be implemented;

FIG. 4 shows a DNN overall encoding architecture using at least some embodiment of the encoding method of the present disclosure;

FIG. 5 shows a DNN overall decoding architecture using at least some embodiment of the encoding method of the present disclosure;

FIG. 6 shows an example of a method for decoding a tensor of a DNN encoded in a bitstream, according to an embodiment of the present disclosure;

FIG. 7 shows an example of a method for encoding tensors of a DNN in a bitstream, according to an embodiment of the present disclosure.

FIG. 8 illustrates an example of a part of a bitstream comprising data representative of a first tensor of at least one layer of a Deep Neural Network, according to an embodiment. It is to be noted that the drawings illustrate example embodiments and that the embodiments of the present disclosure are not limited to the illustrated embodiments.

### DETAILED DESCRIPTION

Many technical fields can involve the processing, with computer means, of large volume of data. Such processing can involve data compression and/or decompression of data, for a purpose a storage or of transmission of at least a part of such data for instance. Examples of compression and/or decompression of streams containing large amount of data can be found in the technical field of video processing, or in technical fields involving Deep Learning techniques.

Embodiments of the present disclosure are detailed hereinafter in link with Deep Neural Networks (DNNs) as an exemplary and not limitative purpose. It is clear however that the present disclosure can also apply to the compression/decompression of other large amount of data, like in the technical field of video processing. For instance, the present disclosure can apply to the compression/decompression of a tensor obtained by a Deep Learning Algorithm from at least one image.

Deep Neural Networks (DNNs) have shown state of the art performance in variety of domains such as multimedia processing, computer vision, speech recognition, natural language processing, etc. This performance however can come at the cost of massive computational cost as DNNs tend to have a huge number of parameters often running into millions, and sometimes even billions.

This can lead for instance to prohibitively high inference complexity. In simple words, inference is the deployment of a DNN, once trained, for processing input data, in view of their classification for instance. Inference complexity can be defined as the computational cost of applying trained DNN to input data for inference. Inference complexity can be defined as the computational cost of applying trained DNN to test data for inference.

This high inference complexity can thus be an important challenge for using DNNs in environments involving an electronic device with limited hardware and/or software resource, for instance mobile or embedded devices with resource limitations like battery size, limited computational power, and memory capacity etc.

Deep Neural Networks are made up of several layers. A layer is associated with a set of parameters that can be obtained for instance during a training of the DNN. These parameters (like Weights and/or Biases) are stored as multi-dimensional arrays (also referred to herein as “tensors”). In the following, for simplicity purpose, the term “matrix can sometimes be used to denote a set of parameters (e.g. parameters of a given layer). It is to be understood, however, that some embodiments of the methods of the present disclosure can also be applied to tensors of parameters with more than two dimensions, such as 2D convolutional layers which usually contain 4D tensors of parameters. The huge number of parameters of DNNs can require a large bandwidth for deployment of DNNs (or solutions including DNNs) in distributed environments.

At least some embodiments of the present disclosure apply to the compression and/or decompression (decoding) of at least some parameters of at least one DNN (for instance a pre-trained DNN). Indeed, compression can facilitate the transmission and/or storage of the parameters of the at least one DNN. More precisely, at least some embodiments of the present disclosure apply to the compression of parameters of at least one tensor associated with at least one layer of at least one Deep Neural Network.

Depending upon embodiments of the present disclosure, the layers (or sub-layers) can be of different types. For instance, in some embodiments, all the at least one layer can be convolutional layer(s), or fully connecter layer(s), or the at least one layer can comprise at least one convolutional layer and/or at least one fully connecter layer.

Some embodiments of the present disclosure relate more specifically to compression solutions including, or at least that may include, decomposition of at least one tensor so as to improve the efficiency of the compression for instance, and/or to decoding solutions including, or at least that may include, reconstruction of at least one tensor. The decomposed at least one tensor can be for instance at least one tensor of one or more layer(s) to be compressed of one or more DNNs, The reconstructed at least one tensor can be for instance at least one tensor of the same shape than at least one tensor, that has been decomposed, of one or more layer(s) to be compressed of one or more DNNs,

According to some embodiments of the present disclosure, decomposition of a tensor can be obtained by using a Low Rank (LR) technology and/or a Low Displacement Rank (LDR) technology.

When tensor decomposition is used to compress large tensors of weights, at least two smaller tensors are produced and further compressed, quantized and entropy coded to be stored or transmitted within a bitstream.

As a non-limitative example, while some embodiments can be applied in non-standardized technologies, some embodiments can be used in contexts of standards for DNN compression/decompression, like the upcoming standard ISO/MPEG7 relating to compressed representations of neural networks for multimedia content description and analysis, which is denoted hereinafter more simply MPEG NNR.

At least some embodiments of the present disclosure propose a syntax structure as well as a mechanism for decomposing tensors and reconstructing tensors from multiple decoded tensors.
More precisely, according to some embodiments, when tensor decomposition is used to compress large tensors of weight, at least two smaller tensors can be produced (and input to quantization, at least some of the output of quantizing being then encoding for instance). For instance, in an exemplary embodiment where decomposition is based on Low Rank (LR), Low Rank approximations can represent an original matrix of weights as a product:

Ŵₖ=GₖHₖ^{T} (1)

where Gₖ is a m×rₖ matrix and Hₖ is n×rₖ matrix that can be derived from a Single Value Decomposition (SVD).
At the decoder, two options can be envisioned when using this compression technique:
Either the device/implementation of the inference of the decoded model supports such decomposition. In that case, the decoder can output the tensors G and H as is,
Or the original graph with the original tensor shapes are required by the inference engine. In this case, a reconstruction needs to be performed (for instance by the decoder).

At least some embodiments of the present disclosure provide a syntax for enabling such condition as well as a mechanism for reconstructing the tensors in their original shape. Indeed, inventors have cleverly noticed that no solution has been proposed yet for reconstructing, for instance at a decoder at the time of the decoding of the model, an original shape of a tensor from the tensors obtained by decomposition of this tensor.

For instance, in the current specification draft of MPEG NNR, the current assumption is that the tensors resulting from decomposing an original tensor are output by the decoder.

This can be an issue when the original tensor shapes are needed by the inference engine as explained above.

At least some embodiments of the present disclosure invention help to address this issue. It is to be pointed out that the embodiments of the methods of the present disclosure detailed herein can be implemented in many compression solutions and are not limited to a specific standard, even if at least some of the embodiments can for instance apply in the context of some compression standards, like some draft standard developed by ISO/MPEG7.

As shown in the above equation (1), in an exemplary embodiment where the Tensor W is a 2D-Matrix, after decoding G and H^{T}, a matrix multiplication of the two matrices is needed to be performed to obtain the original matrix shape.

In the above exemplary embodiments, a LR decomposition can be used for the original tensor. However, depending upon embodiments, or depending upon tensors of the one or more DNN, different decompositions can be performed. In the case of a tensor of a convolution or depth-wise convolution layers for instance, a tensor can be reshaped into a 2-dimension matrix, enabling LR/LDR methods.

This present disclosure describes necessary syntax and processes for permitting to reconstruct tensors.

Notably, some embodiments of the present disclosure, adapted for instance to reconstruct an original tensor from one or more tensor units, propose a mechanism involving a buffer of tensors to keep the previously decoded tensors in order to perform the reconstruction, like for instance (in the exemplary use case introduced above in link with equation (1)) the previously decoded G and/or H matrices in order to perform the reconstruction of W.

In the following, a Decoded Tensor Buffer (DTB) is introduced, which can contain multiple already decoded tensors in memory. For instance, in the above exemplary embodiment, the decoded tensors G and H are added to the buffer when they are the first of the two tensors (G and H) to be decoded for a given layer. More precisely, for a given layer, the decoded tensor G (respectively the decoded tensor H) is added to the buffer when the tensor H (respectively the tensor G) has not yet been decoded.

Then, when the corresponding tensor in the same layer is decoded, the reconstruction of a tensor having the shape of the original tensor can be triggered, and the memory taken by the saved tensor in the DTB can be freed.

In at least some embodiments of the present disclosure, once an original tensor has been decomposed in several tensors, the several resulting tensors can be encoded and decoded separately (in other words independently).

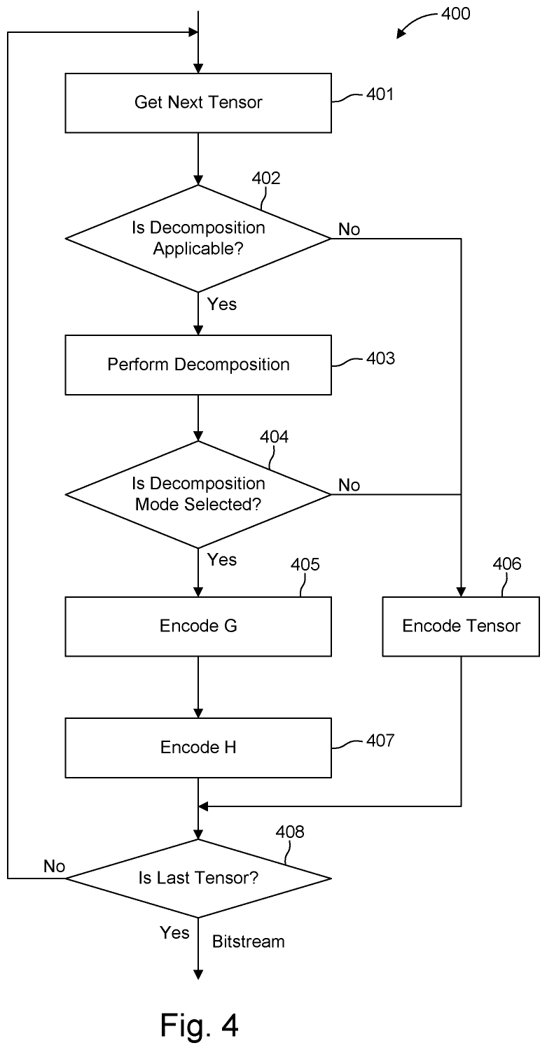

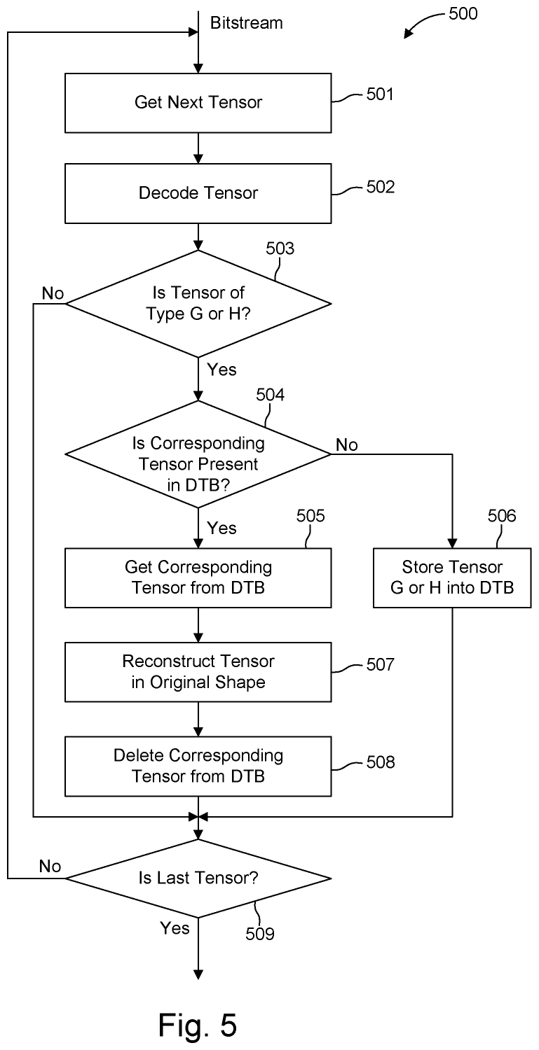

FIGS. 4 and 5 illustrate respectively at a high level a general process for encoding/decoding parameters of at least one tensor of at least one layer of at least one DNN, that can be used in at least some embodiments of the present disclosure. The method of FIG. 4 can be performed in an encoding device (or encoder) for instance and the method of FIG. 5 in a decoding device (or decoder) for instance.

As illustrated by FIG. 4, at the encoder, the method can comprise obtaining (or getting) 401 parameters of a tensor (also called herein “original tensor”), associated with a layer, that is to be compressed. The obtaining can for instance be performed by retrieving the parameters of the at least one tensor from a storage unit, or by receiving the parameters from a data source via a communication interface.

In some embodiments, each obtained tensor can be decomposed.

In other embodiments, as in the embodiment of FIG. 4, the decomposition can be performed conditionally. Indeed, as an example, decomposition can be sometimes not applicable. Tensor decomposition cannot be performed on biases which are 1D arrays for instance. Furthermore, in some embodiments, other factors (like coding cost of the original tensor) can also be taken into account to determine if a decomposition will be applied to a tensor. For instance, a mode can be associated (403) to a tensor, and/or to the layer of a tensor, or to one or more layers, including the layer of the tensor. At least one first value of the mode can be representative of a decomposition to be performed on the tensor, if applicable, and/or at least one second value of the mode can be representative of a tensor being processed without being applied decomposition.

In the exemplary embodiment of FIG. 4, the method can comprise testing (402) if decomposition can be applicable to the input tensor and, if the tensor that can be decomposed (402), testing (403) if the decomposition mode (e.g. the first value of the mode) is selected.

If the decomposition mode is selected by the encoder (404), the method can comprise decomposing the tensors and encoding the resulting tensors (for instance encoding (405) the tensor G and encoding the tensor H (407)).

In the exemplary use case of FIG. 4, in case where decomposition is not chosen (decomposition mode not selected) or is not applicable, the input tensor can be directly encoded (406).

The output of the encoding is used to compose the bitstream.

This process can be iterated for several input tensors, for instance for all tensors in the model to quantize and/or encode (408).

In some embodiments, the method can further comprise, prior to the encoding, reducing the number of parameters (or Weights or Biases) of the Neural Network by utilizing the inherent redundancies in the Neural Network. For instance, original tensors of parameters of at least one layer of the DNN or tensors resulting from the decomposition of original tensors of parameters of at least one layer of the DNN can be made sparse. This reducing is optional and can be omitted in some embodiments and/or for some tensors of some layers

The encoding can comprise quantizing parameters (like Weights and Biases) of at least one tensor (e.g. either the tensors output by the decomposition of a tensor of a layer of the Neural Network, or the tensor itself when no decomposition is performed) and lossless entropy coding of the quantized information to represent them with a smaller number of bits.

In some embodiments, when several layers of a DNN are to be encoded, the method can be performed iteratively layer per layer, until the end of the encoding of parameters of the last layer to be encoded.

In some embodiments, as in the illustrated embodiment of FIG. 4., tensors of a same layer are not required to be encoded sequentially and can be encoded in parallel or inserted between other tensors of other layers. Indeed, encoding can be based on units at the tensor level, weights and biases of a same layer being contained in same or different tensor units (as in an upcoming MPEG NRR draft for instance).

FIG. 5 shows the corresponding processing performed at the decoding side on the tensors decoded from a bitstream, for instance a bitstream obtained by the encoding method already described in line with FIG. 4. In the exemplary embodiment of FIG. 5, a tensor is first parsed and identified (501), for instance using its unit header and/or a Layer Parameter Set. For instance, the exemplary syntax presented in more details hereinafter can use the associated High-Level Syntax referenced by lps_layer_parameter_set_id in the unit header which will point at the correct Layer Parameter Set. According to FIG. 5, the tensor payload can be decoded (502). In the exemplary embodiment of FIG. 5, where the decomposition is of LR or LDR type, If the decoded tensor is of type TENSOR_G or TENSOR_H (503) (denoted G and H in the figure, respectively) the steps 505 to 508 can be performed (see hereinafter). Otherwise, if it is not the last decoded tensor (509), the next tensor can be accessed from the bitstream. In the case where the current tensor is of type TENSOR_G or TENSOR_H, the corresponding tensor belonging to the same layer is searched in the Decoded Tensor Buffer. This can be done by looking for a tensor associated with an identifier (like a reference identifier “ref_id”) specifying the same layer than the current tensor. With the exemplary syntax introduced below, such a reference identifier (e.g. “ref_id”) can be a syntax element from the tensor unit header that maps tensor units to uniquely identifiable data structures that depend on the topology storage format, e.g. ONNX or NNEF.

If the corresponding tensor is present, it is fetched from the DTB (505) and both current and fetched (507) tensors are used to reconstruct a tensor in the shape (508) of the original tensor (i.e. the obtained tensor of step 401). It is to be pointed out that in many embodiments, while having the same dimensions as the original tensor, the reconstructed tensor is however different from the original tensor.

If the corresponding tensor is not present in the DTB, the method 500 can comprise storing the current tensor in the DTB for future use (506).

In any cases (in other words after having decoded the current tensor unit) (step 509), the method can further comprise checking if the current tensor is the last in the bitstream (509) and the method outputs the model if it is the case or access the next tensor unit otherwise.

At the decoder, as illustrated by FIG. 5, the decoding can include some inverse operations (compared to the operations of the encoder side). For instance, the decoding method can include parsing/entropy decoding 510 of the input bins to extract the metadata and/or quantized form of the parameters. Inverse quantization 520 can then applied to derive the final values of the parameters of a tensor.

When several tensors (of several layers for instance) are to be decoded, the method 500 can be performed until all the several tensors are decoded.

Some embodiments of the present disclosure can comprise transmitting/receiving signaling information between an encoder and a decoder. This signaling information is presented in the present disclosure in link with an exemplary, non-limitative, syntax. This exemplary syntax is mainly based, for the ease of explanation, on a syntax used in an exemplary MPEG NNR draft standard (like N19225—Working Draft 4 of Compression of neural networks for multimedia content description and analysis International Organization for Standardization ISO/IEC JTC1/SC29/WG11, April 2020.

The following syntax is just an exemplary syntax that does not limit the present disclosure. For instance, numbers of bits used for syntax elements are exemplary embodiments. For ease of understanding, in the exemplary syntax, the following identifiers and clauses according to embodiments of the present disclosure have been added with a numbering of sections and tables being kept aligned with the current exemplary working draft of the MPEG-NNR.
With this exemplary syntax, the following tensor operations can be added:
MatrixProd (array_name_1[ ], array_name_2[ ]) which returns the matrix product of array_name_1 by array_name_2.
TensorReshape (array_name[ ], tensor_dimension[ ]) which returns the reshaped tensor array_name[ ] with the specified tensor_dimension[ ], without changing its data.
Furthermore, definitions of the following terms are provided:
bin: One bit of a bin string.
binarization: A set of bin strings for all possible values of a syntax element.
binarization process: A unique mapping process of all possible values of a syntax element onto a set of bin strings.
bin string: An intermediate binary representation of values of syntax elements from the binarization of the syntax element.
bitstream: A sequence of bits, that forms the representation of coded units and associated data forming one or more coded Neural Network Models
decoded tensor buffer (DTB): A buffer holding decoded tensors/units for reference.

When decoding at least a part of a bitstream (simply said the “decoding process”), the following conditions can be applied with the exemplary detailed syntax:
An information that is required for decoding an NNR Unit of the NNR bitstream can be signaled as part of the NNR bitstream. If such information is not part of the NNR bitstream, then it can be provided to the decoding process by other means (e.g. out-of-band topology information or parameters required for decoding but not signaled or carried in the NNR bitstream)
The decoding process can be initiated with an NNR unit of type NNR_STR (see table below). With the reception of the NNR_STR unit, the decoder can reset its internal states and get ready to receive an NNR bitstream. The presence and cardinality of preceding NNR units can be specified in some subclauses and/or annexes
The buffer DTB is set to be empty (the DTB fullness is set equal to 0) at the initiating of the decoding processing.
   With the exemplary syntax detailed herein, following the table references the different unit types. Above mentioned NNR_STR specifies the start unit of an NNR bitstream.

TABLE
NNR Unit Types

| nnr_unit_type | Identifier | NNR Unit Type | Description |
|---|---|---|---|
| 0 | NNR_STR | NNR start unit | Compressed neural network |
| | | | bitstream start indicator |
| 1 | NNR_MPS | NNR model parameter set | Neural network global metadata and |
| | | data unit | information |
| 2 | NNR_LPS | NNR layer parameter set | Metadata related to a partial |
| | | data unit | representation of neural network |
| 3 | NNR_TPL | NNR topology data unit | Neural network topology information |
| 4 | NNR_QNT | NNR quantization data unit | Neural network quantization |
| | | | information |
| 5 | NNR_NDU | NNR compressed data unit | Compressed neural network data |
| 6 | NNR_AGG | NNR aggregate unit | NNR unit with payload containing |
| | | | multiple NNR units |
| 7...127 | NNR_RSVD | Reserved | MPEG-reserved range |
| 128..255 | NNR_UNSP | Unspecified | Unspecified range |

According to some embodiments of the present disclosure, it is proposed to specify NNR tensor types in case of tensor decomposition. For instance, the following exemplary syntax can be used, in link with the exemplary MPEG NNR draft standard:

### 6.2 NNR Decomposition Identifiers

With the exemplary syntax detailed herein, a table can specify NNR tensor types in case of tensor decomposition.

TABLE
NNR decomposition tensor type identification

| Parameter | | |
|---|---|---|
| identifier | Parameter description | nnr_decomoosition_tensor_type |
| TENSOR_G | Tensor of type G, | 0 |
| TENSOR_H | Tensor of type H | 1 |
| TENSOR_OTHER | Tensor of type other than TENSOR_G and | 2 |
| | TENSOR_H, e.g. Biases, batch norm . . . | |

### Tensor Output

At the decoder side, the tensor processing can be performed once per NNR compressed payload, after decoding the unit header (e.g. nnr_compressed_data_unit_header with the exemplary syntax) and the compressed payload.

In the exemplary embodiment detailed, the output of the processing of current tensor can be specified as follows:
If output_original_graph is equal to 0 or if lps_tensor_decomposition_flag is equal to 0 or if nnr_decomposition_tensor_type is equal to “TENSOR OTHER”, the current tensor is output
Otherwise if there are no tensors with an identifier (e.g. ref_id) specifying the same layer in the DTB, add the current tensor into the DTB. No tensor is output.
Otherwise (the current nnr_decomposition_tensor_type specifies a tensor of type “TENSOR G” or “TENSOR_H” and there exists a tensor with an identifier (e.g. ref_id) specifying the same layer in the DTB), invoke the reconstruction of the tensor in its original shape, as specified above, passing both the current tensor of type “TENSOR G” or “TENSOR_H”, respectively, and its corresponding tensor in the DTB, of type “TENSOR_H” or “TENSOR_G”, respectively. The latter is deleted from the DTB. The returned tensor is output.

### Reconstruction of Tensors in the “Original” Shape

The reconstruction of tensors having the shape of an original tensor can be performed after decoding all tensors resulting from the decomposition of the original tensor.

For instance, in embodiments where an original tensor has been decomposed in a tensor G and a tensor H, the reconstruction can happen after decoding a tensor (e.g. a tensor of type “TENSOR_G” or “TENSOR_H”) if the corresponding tensor (e.g. a tensor with an identifier (e.g. ref_id) specifying the same layer) is present in the DTB, as explained above.

In the exemplary syntax described herein, the inputs to this reconstruction can include
A tensor tensor_h[ ] of type “TENSOR_H”
The array tensor_dimensions_h[ ] corresponding to the dimensions of tensor_h[ ], as defined by its decoded syntax tensor_dimensions from the corresponding nnr_compressed_data_unit_header
A tensor tensor_g[ ] of type “TENSOR_G”.
An array tensor_dimensions_g[ ] corresponding to the dimensions of tensor_g[ ], as defined by its decoded syntax tensor_dimensions
The values tensor reconstruction mode and tensor reconstruction additional info from the layer parameter set of the tensor just decoded header.

In the exemplary embodiment described, the output of this reconstruction is a current tensor array_w having the same shape as the original tensor (also called herein original shape). According to some embodiments of the present disclosure, the current tensor array w can be computed by taking account of a reconstruction mode of the tensor. In exemplary syntax detailed herein, the following table can be used for specifying the reconstruction mode of a tensor in the bitstream:

TABLE 1
Specification of the reconstruction mode

| | Name of tensor | |
|---|---|---|
| | reconstruction | |
| tensor_reconstruction_mode | mode | Description |
| 0 | NNR_FC | Fully connected layer |
| 1 | NNR_CONV | Convolutional layer |
| 2 | NNR_DWCONV | Depth-wise |
| | | convolutional layer |
| 3-7 | NNR_URM | Unused reconstruction |
| | | modes |

The current tensor array w can be computed as the following:

```
if ( tensor_reconstruction_mode == NNR_FC )
  array_w = MatrixProd( tensor_g, tensor_h )
else if ( tensor_reconstruction_mode == NNR_CONV ) {
  rank = tensor_dimensions_g [3]
  wShape = [tensor_dimensions_g [0], tensor_dimensions_g [1],
    tensor_dimensions_g [2], tensor_dimensions_h [3]]
  prod = MatrixProd( TensorReshape (g, [−1, rank]), TensorReshape
  (h, [rank, −1])
  array_w = TensorReshape (prod, wShape)
}
else if ( tensor_reconstruction_mode == NNR_DWCONV ) {
  kernel = tensor_reconstruction_additional_info[0]
  wShape = [kernel, kernel, −1,1]
  array_w = TensorReshape (MatrixProd( g, h ), wShape)
}
```

As for the High-Level Syntax, with the exemplary draft standard MPEG-NNR, some elements can be added to some tables of the exemplary draft standard as the following:

### 8.2.4.6 NNR Compressed Data Unit Header Syntax

| | Descriptor |
|---|---|
| nnr_compressed_data_unit_header( ) { | |
| nnr_layer_parameter_set_id | u(8) |
| nnr_compressed_data_unit_payload_type | u(5) |
| nnr_multiple_topology_elements_present_flag | u(1) |
| nnr_decompressed_data_format_present_flag | u(1) |
| input_parameters_present_flag | u(1) |
| if (nnr_multiple_topology_elements_present_flag = = 1) | |
| topology_elements_ids_list( ) | |
| Else | |
| ref_id | st(v) |
| if (nnr_compressed_data_unit_payload_type = = | |
| NNR_PT_CB_FLOAT32) { | |
| codebook_zero_offset | u(8) |
| codebook_size | u(16) |
| For ( j = 0 ; j < codebook_size; j++ ) { | |
| codebook[j] | flt(32) |
| } | |
| } | |
| if (lps_tensor_decomposition_flag == 1) { | |
| nnr_decomposition_tensor_type | u(2) |
| } | |
| if (nnr_decompressed_data_format_present_flag = = 1) | |
| nnr_decompressed_data_format | u(7) |
| if (input_parameters_present_flag = = 1) { | |
| tensor_dimensions_flag | u(1) |
| cabac_unary_length_flag | u(1) |
| if (tensor_dimensions_flag = = 1) | |
| tensor_dimensions( ) | |
| If (cabac_unary_length_flag = = 1) | |
| cabac_unary_length | u(8) |
| } | |
| byte_alignment( ) | |
| } | |

where
nnr_layer_parameter_set_id specifies for instance the value of lps_layer_parameter_set_id for the compressed unit in use. The value of unit_layer_parameter_set_id can be in the range of 0 to 63, inclusive for instance.
nnr_decomposition_tensor_type specifies the tensor type in the case of tensor decomposition, as defined above for instance

### 8.2.5.2 NNR Model Parameter Set Payload Syntax

| | Descriptor |
|---|---|
| nnr_model_parameter_set_payload( ) { | |
| mps_model_parameter_set_id | u(4) |
| topology_carriage_flag | u(1) |
| sparsification_flag | u(1) |
| mps_tensor_decomposition_flag | u(1) |
| quantization_method_flags | u(6) |
| if ((quantization_method_flags & NNR_QSU) = = | |
| NNR_QSU) { | |
| qp_density | u(3) |
| quantization_parameter | i(13) |
| } | |
| If (sparsification_flag = = 1) { | |
| sparsification_performance_map( ) | |
| } | |
| if (mps_tensor_decomposition_flag) { | |
| output_original_graph | u(1) |
| if (output_original_graph) | |
| mps_max_dec_tensor_buffering_minus1 | u(6) |
| } | |
| ctu_partition_flag | u(1) |
| if(ctu_partition_flag){ | |
| max_ctu_dim_flag | u(2) |
| nnr_reserved_zero_5bits | u(5) |
| }else{ | |
| nnr_reserved_zero_7bits | u(7) |
| } | |
| } | |

where
mps_model_parameter_set_id provides an identifier for the MPS for reference by other syntax elements. The value of mps_model_parameter_set_id can be set in the range of 0 to 15, inclusive.
decomposition_flag equal to 1 specifies that tensor decomposition was applied to at least one tensor of at least one layer of the model.
output_original_graph equal to 1 specifies that the decoder outputs the tensors of weights in their original shape when tensor decomposition is used.
mps_max_dec_tensor_buffering_minus1 plus 1 specifies the maximum required size of the decoded tensor buffer for the NNR model, in units of tensor storage buffers. The value of mps_max_dec_tensor_buffering_minus1 can be set in the range of 0 to 63

### 8.2.5.3 NNR Layer Parameter Set Unit Payload Syntax

| | Descriptor |
|---|---|
| nnr_layer_parameter_set_unit_payload( ) { | |
| lps_model_parameter_set_id | u(4) |
| lps_layer_parameter_set_id | u(6) |
| independently_decodable_flag | u(1) |
| lps_tensor_decomposition_flag | u(1) |
| sparsification_flag | u(1) |
| quantization_method_flags | u(6) |
| If ((quantization_method_flags & NNR_QSU) = = | |
| NNR_QSU) { | |
| quantization_step_size | u(8) |
| } | |
| If ((quantization_method_flags & NNR_QCB) = = | |
| NNR_QCB) { | |
| quantization_map( ) | |
| } | |
| if (lps_tensor_decomposition_flag) { | |
| tensor_reconstruction_mode | u(3) |
| tensor_reconstruction _additional_info_count | u(5) |
| for (j = 0; j < (tensor_reconstruction | |
| _additional_info_count); j++ ) | |
| { | |
| tensor_reconstruction_additional_info[j] | u(16) |
| } | |
| If (sparsification_flag = = 1) { | |
| sparsification_performance_map( ) | |
| } | |
| } | |

where
lps_model_parameter_set_id specifies the value of the mps_model_parameter_set_id of the active LPS. The value of lps_model_parameter_set_id can be set in the range of 0 to 15, inclusive.
lps_layer_parameter_set_id provides an identifier for the LPS for reference by other syntax elements. The value of lps_layer_parameter_set_id can be set in the range of 0 to 63, inclusive.
lps_tensor_decomposition_flag equal to 1 specifies that tensor decomposition is used for this layer.
tensor_reconstruction_mode specifies the mode which is used to reconstruct the current tensor in its original shape from decomposed decoded tensors as defined above.
tensor_reconstruction_additional_info_counts specifies the number of parameters that can be required to perform the reconstruction of decomposed tensors
tensor_reconstruction_additional_info[i] specifies an array of parameters which can be required for reconstructing decomposed tensors. (For example, in the case of a depth-wise convolutional layer, tensor_reconstruction_additional_info_counts can be set to 1 and tensor_reconstruction_additional_info[0] specifies the kernel size of the convolution).

### Variants:

Some exemplary embodiments have been detailed above. The present disclosure also encompasses many variants of the above embodiments

For instance, some embodiments of the present disclosure can relate to the following variants
First Variant: Version without Output_Original_Graph

According to a first variant, the variable output_original_graph (introduced above) can be omitted. In this variant, the reconstruction depends on a topology_storage_format variable. With regards to the exemplary NNR tables introduced above, the table “NNR model parameter set payload syntax” can thus be modified (since the variable output_original_graph is not required).

With the exemplary syntax detailed herein, in link with the MPEG NNR standard, this leads to the following table

### 8.2.5.2 NNR Model Parameter Set Payload Syntax

| | Descriptor |
|---|---|
| nnr_model_parameter_set_payload( ) { | |
| mps_model_parameter_set_id | u(4) |
| topology_carriage_flag | u(1) |
| sparsification_flag | u(1) |
| mps_tensor_decomposition_flag | u(1) |
| quantization_method_flags | u(6) |
| if ((quantization_method_flags & NNR_QSU) = = | |
| NNR_QSU) { | |
| qp_density | u(3) |
| quantization_parameter | i(13) |
| } | |
| If (sparsification_flag = = 1) { | |
| sparsification_performance_map( ) | |
| } | |
| If (mps_tensor_decomposition_flag == 1) | |
| mps_max_dec_tensor_buffering_minus1 | u(6) |
| ctu_partition_flag | u(1) |
| if(ctu_partition_flag){ | |
| max_ctu_dim_flag | u(2) |
| nnr_reserved_zero_5bits | u(5) |
| }else{ | |
| nnr_reserved_zero_7bits | u(7) |
| } | |
| } | |

For the reconstruction method, the following applies:

### Tensor Output

This process can be invoked once per NNR compressed payload, after decoding of the unit header nnr_compressed_data_unit_header and the compressed payload.
The output of the current tensor can be specified as follows:
If lps_tensor_decomposition_flag is equal to 0 or nnr_decomposition_tensor_type is equal to “TENSOR_OTHER”, or the topology_storage_format specifies a topology that supports the inference using decomposed matrix, the current tensor is output
Otherwise if there are no tensors with the same “ref_id” in the DTB, add the current tensor into the DTB with its “ref_id”. No tensor is output.
Otherwise (the current nnr_decomposition_tensor_type specifies a tensor of type “TENSOR G” or “TENSOR_H” and there exists a tensor with the same “ref_id” in the DTB), invoke the reconstruction of the tensor in its original shape, as specified above, passing both the current tensor of type “TENSOR G” or “TENSOR_H”, respectively, and its corresponding tensor in the DTB, of type “TENSOR_H” or “TENSOR_G”, respectively. The latter is deleted from the DTB. The returned tensor is output.
   With the exemplary syntax detailed herein, the topology_storage_format variable can be defined (in the section 8.3.2.3.4 for instance) as shown below:

### 8.3.2.3.4 NNR Topology Unit Header Semantics

topology_storage_format specifies the format of the stored neural network topology information, as specified below:

| topology_storage_format | | |
|---|---|---|
| value | Identifier | Description |
| 0 | NNR_NNEF | Neural network topology |
| | | information is stored in |
| | | NNEF format as specified |
| | | in Neural Network |
| | | Exchange Format, The |
| | | Khronos NNEF Working |
| | | Group, Version 1.0.3, |
| | | 2020 Jun. 12 |
| | | (https://www.khronos.org/ |
| | | registry/NNEF/specs/1.0/ |
| | | nnef-1.0.3.pdf) |
| 1 | NNR_ONNX | Neural network topology |
| | | information is stored as |
| | | ONNX messages (Open |
| | | Neural Network Exchange, |
| | | VERSION 6, 2019 Sep. |
| | | 19 (https://github.com/ |
| | | onnx/onnx/blob/master/ |
| | | onnx/onnx.proto)) |
| 2..127 | NNR_RSVD | MPEG-reserved range |
| 128..255 | NNR_UNSP | Unspecified range |

### Second Variant: Decomposition Performance Map

In a second variant, information can be provided in the signaling regarding a performance of the decomposition process. For instance, such an information can be representative of a mapping between different Mean Square Error (MSE) values between the decomposed tensors and their original version and resulting Neural Network (NN) inference accuracies.
The resulting accuracies can be provided separately for different aspects or characteristics of the output of the NN. For a classifier NN, each MSE value (e.g. threshold) can be mapped to separate accuracies for each class, in addition to an overall accuracy which considers all classes. In some embodiments, classes can be ordered based on the neural network output order, i.e., the order specified during training.
With the exemplary syntax detailed herein, in link with the MPEG NNR standard, the following table can be used

### 8.2.5.2 NNR Model Parameter Set Payload Syntax

| | Descriptor |
|---|---|
| nnr_model_parameter_set_payload( ) { | |
| mps_model_parameter_set_id | u(4) |
| topology_carriage_flag | u(1) |
| sparsification_flag | u(1) |
| mps_tensor_decomposition_flag | u(1) |
| quantization_method_flags | u(6) |
| if ((quantization_method_flags & NNR_QSU) = = | |
| NNR_QSU) { | |
| qp_density | u(3) |
| quantization_parameter | i(13) |
| } | |
| If (sparsification_flag = = 1) { | |
| sparsification_performance_map( ) | |
| } | |
| if (mps_tensor_decomposition_flag) { | |
| output_original_graph | u(1) |
| decomposition_performance_map( ) | |
| mps_max_dec_tensor_buffering_minus1 | u(6) |
| } | |
| ctu_partition_flag | u(1) |
| if(ctu_partition_flag){ | |
| max_ctu_dim_flag | u(2) |
| nnr_reserved_zero_5bits | u(5) |
| }else{ | |
| nnr_reserved_zero_7bits | u(7) |
| } | |
| } | |

where Decomposition_performance_map( ) can be defined for instance as follows:

| | Descriptor |
|---|---|
| decomposition_performance_map ( ) { | |
| count_thresholds | u(8) |
| for (i = 0; i < (count_thresholds-1); i++ ) { | |
| mse_threshold[i] | flt(32) |
| nn_accuracy[i] | flt(32) |
| nn_reduction_ratio[i] | flt(32) |
| count_classes[i] | u(16) |
| for (j = 0; j < (count_classes-1); j++ ) { | |
| nn_class_accuracy[i][j] | flt(32) |
| } | |
| } | |
| } | |

where:
decomposition_performance_map( ) specifies a mapping between different Mean Square Error (MSE) thresholds between the decomposed tensors and their original version and resulting NN inference accuracies. The resulting accuracies are provided separately for different aspects or characteristics of the output of the NN. For a classifier NN, each MSE threshold is mapped to separate accuracies for each class, in addition to an overall accuracy which considers all classes. Classes are ordered based on the neural network output order, i.e., the order specified during training.
count_thresholds specifies the number of decomposition MSE thresholds.
Decomposition_threshold specifies an array of MSE thresholds which are applied to derive the ranks of the different tensors of weights.
nn_accuracy specifies the overall accuracy of the NN (e.g., classification accuracy by considering all classes).
nn_reduction_ratio[i] specifies the ratio between the total number of parameters after tensor decomposition of the whole model and the number of parameters in the original model
count_classes specifies number of classes for which separate accuracies are provided for each decomposition thresholds.
nn_class_accuracy specifies an array of accuracies for a certain class when a certain decomposition threshold is applied.

### Third Variant: Reconstruction in the Case of Units of Type NNR_PT_BLOCK

This third variant is detailed, for the ease of explanation, using an exemplary syntax compatible with an exemplary MPEG NNR draft standard (like N19225—Working Draft 4 of Compression of neural networks for multimedia content description and analysis». International Organization for Standardization ISO/IEC JTC1/SC29/WG11, April 2020), the exemplary syntax including units of type NNR_PT_BLOCK. With such an exemplary syntax, multiple parameters can be present within the unit, e.g. weight tensors that can be optionally decomposed, biases, batch norm parameters, etc. In the context of an NNR_PT_BLOCK unit, the output tensor of weights has to comply with the original shape that can be either transmitted or known by the decoder, through external topology information for instance. If tensor decomposition was applied at the encoder, the reconstruction of the tensor is performed at the decoder.

In this variant, it is proposed to simplify the process of reconstruction and the required syntax for specifying the sizes of the decomposed tensors G and H, sometimes also called at the decoder RecWeightG and RecWeightH, respectively.
The decoder needs to derive the sizes of G and H tensors, e.g. when the layer is of type convolutional (CONV) or depth-wise convolution (DWCONV). Some embodiments of the present disclosure thus propose to transmit information related to the size of G and/or H tensors. The size of the G and/or H tensor refers to the a size of a dimension of the G and/or H tensor, such as a number of rows, or a number of columns of the tensor.
According to an exemplary syntax, such information can be added to the High Level Syntax (HLS), for instance in a compressed data unit header. For instance, in an exemplary syntax (like an exemplary syntax compatible with some draft of MPEG NNR), the information related to the tensors size of G and/or H and the rank decomposition_rank can be transmitted to the decoder in the NNR compressed data unit header, as follows:

| | Descriptor |
|---|---|
| nnr_compressed_data_unit_header( ) { | |
| nnr_compressed_data_unit_payload_type | u(5) |
| nnr_multiple_topology_elements_present_flag | u(1) |
| nnr_decompressed_data_format_present_flag | u(1) |
| input_parameters_present_flag | u(1) |
| if (nnr_multiple_topology_elements_present_flag = = 1) | |
| topology_elements_ids_list( ) | |
| else | |
| ref_id | st(v) |
| if (nnr_compressed_data_unit_payload_type = = | |
| NNR_PT_CB_FLOAT32) { | |
| codebook_zero_offset | u(8) |
| codebook_size | u(16) |
| for( j = 0 ; j < codebook_size; j++) { | |
| codebook[j] | flt(32) |
| } | |
| } | |
| if (nnr_decompressed_data_format_present_flag = = 1) | |
| nnr_decompressed_data_format | u(7) |
| if (input_parameters_present_flag = = 1) { | |
| tensor_dimensions_flag | u(1) |
| cabac_unary_length_flag | u(1) |
| block_parameter_types | u(4) |
| if ((block_parameter_types & 0x01) != 0){ | |
| decomposition_rank | u(16) |
| g_number_of_rows | u(16) |
| } | |
| if (tensor_dimensions_flag = = 1) | |
| tensor_dimensions( ) | |
| If (cabac_unary_length_flag = = 1) | |
| cabac_unary_length | u(8) |
| } | |
| if( count_tensor_dimensions > 1) | |
| scan_order | u(8) |
| byte_alignment( ) | |
| } | |

Where g_number_of_rows specifies the number of rows of matrix g in the case where the reconstruction is performed for decomposed tensors in an NNR unit of type NNR_PT_BLOCK. This information can enable the decoder to perform the reconstruction in the case of an NNR_PT_BLOCK as follows (with (block_parameter_types & 0x01)!=0 specifying that Low rank decomposed weights are present)
If (block_parameter_types & 0x01)!=0, the following applies:
The decoding process for an integer weight tensor can be invoked with input variable TensorDims set to [g_number_of_rows, decomposition_rank]. A variable RecWeightG can be set to the output variable RecParam.
The number of columns h_number_of_columns of matrix h in the case where the reconstruction is performed for decomposed tensors in an NNR unit of type NNR_PT_BLOCK can be obtained by

$$h\_number \_of \_columns = \frac{{\prod }_{i = 0}^{tensor\_dimensions \_count - 1} tensor\_dimensions [ i ]}{g\_number \_of \_rows}$$

The decoding process for an integer weight tensor can then be invoked with input variable TensorDims set to [decomposition_rank, h number of columns]. A variable RecWeightH can be set to the output variable RecParam.
   Variable RecWeight can be derived as follows:

RecWeight=TensorReshape(RecWeightG*RecWeightH,tensor_dimensions)

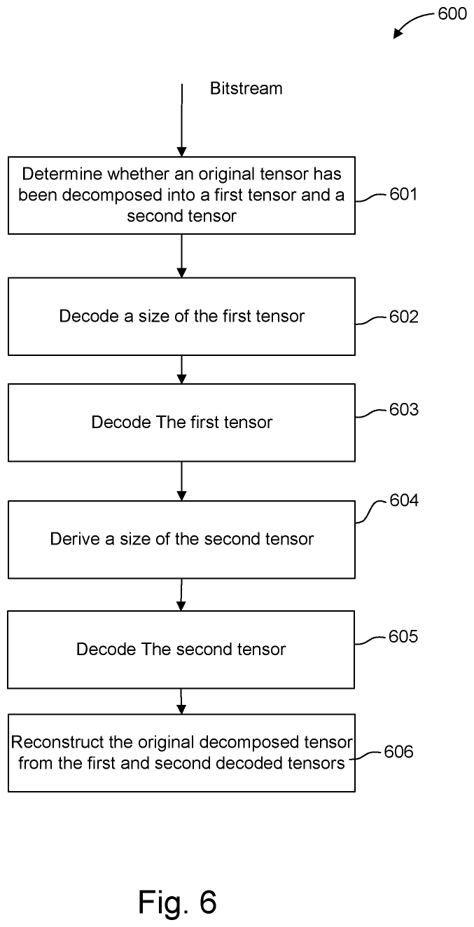

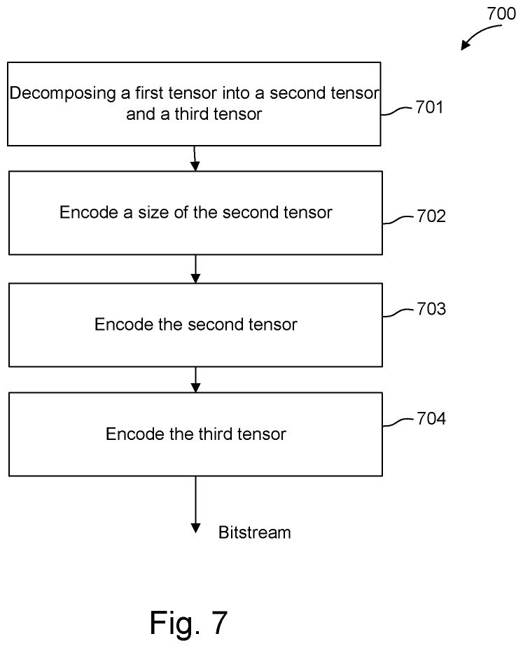

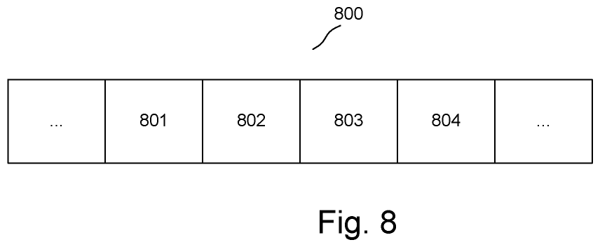

With the above exemplary syntax, the variable g_number_of_rows can be now available from the unit header. Then, the variable h_number_of_columns can be derived since the dimensions of the output tensor_dimensions (tensor_dimensions) are known. Such an embodiment can thus enable for instance the decoder to separately decode tensors G and H and then reshape their product to obtain the reconstructed tensor RecWeight.
In other variants, the variable h_number_of_columns can be transmitted (for instance similarly to the g_number_of_rows in the third variant detailed above, for being available from the unit header), the g_number_of_rows being derived at the decoder side.
In still other variants, both the variables g_number_of_rows and h_number_of_columns can be transmitted (for instance similarly to the g_number_of_rows in the third variant detailed above, for being both available from the unit header), thus avoiding the corresponding computation at the decoder side for instance.
FIG. 6 illustrates an example of a method 600 for decoding tensors resulting for a tensor decomposition, according to an embodiment as described above. A bitstream comprising coded data representative of a neural network is input to the decoder. At 601, it is determined whether an original tensor has been decomposed into a first tensor and a second tensor, e.g the first and second tensors are respectively a G and H tensors resulting from a low rank decomposition. At 602, if the current unit to decode comprises weights a tensor resulting from a tensor decomposition, a size of the first tensor is decoded from the bitstream. For instance, in the case of a G tensor, the size of the first tensor is a number of rows of the G tensor.
At 603, the first tensor is decoded based on the decoded size. At 604, a size of the second tensor is derived from the decoded size. For instance, when the second tensor is an H tensor, the size of the second tensor is a number of columns of the H tensor. At 605, the second tensor is decoded based on the derived size. At 606, the decoder can reconstruct the decomposed tensor from the decoded first and second tensors.
In some embodiments, the bitstream contains the size of the second tensor instead of the size of the first tensor, or both sizes.
FIG. 7 shows an example of a method 700 for encoding tensors of a DNN in a bitstream, according to an embodiment described above. At 701, a first tensor is decomposed into a second tensor and a third tensor. At 702, a size of the second tensor is encoded in the bitstream. At 703, parameters of the second tensor are encoded in the bitstream. At 704, parameters of the third tensor are encoded in the bitstream. In a variant, the size of the third tensor can also be encoded in the bitstream.
FIG. 8 illustrates an example of a part of a bitstream 800 comprising data representative of a first tensor of at least one layer of a Deep Neural Network generated according to any one of the methods described above. In some embodiments, the data comprises an information 801 indicating that the first tensor is decomposed into a second tensor and a third tensor, a size 802 of at least one of the second tensor and the third tensor, and parameters 803 of the at least one of the second tensor and the third tensor. In a variant, the data comprises also parameters 804 of the other tensor of the at least one of the second tensor and the third tensor.

### Additional Embodiments and Information

This application describes a variety of aspects, including tools, features, embodiments, models, approaches, etc. Many of these aspects are described with specificity and, at least to show the individual characteristics, are often described in a manner that may sound limiting. However, this is for purposes of clarity in description, and does not limit the application or scope of those aspects. Indeed, all of the different aspects can be combined and interchanged to provide further aspects. Moreover, the aspects can be combined and interchanged with aspects described in earlier filings as well.

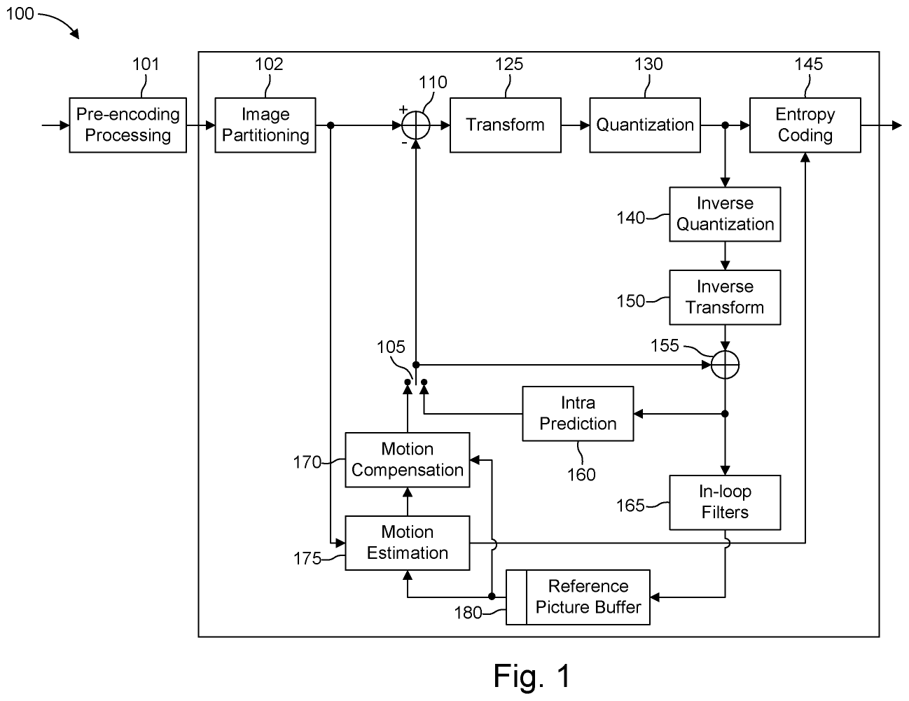

The aspects described and contemplated in this application can be implemented in many different forms. FIGS. 1, 2 and 3 below provide some embodiments, but other embodiments are contemplated and the discussion of FIGS. 1, 2 and 3 does not limit the breadth of the implementations. At least one of the aspects generally relates to encoding and decoding (for instance, video encoding and decoding, and/or encoding and decoding of at least some weights of at least some layer of a DNN), and at least one other aspect generally relates to transmitting a bitstream generated or encoded. These and other aspects can be implemented as a method, an apparatus, a computer readable storage medium having stored thereon instructions for encoding or decoding data according to any of the methods described, and/or a computer readable storage medium having stored thereon a bitstream generated according to any of the methods described.

In the present application, the terms “reconstructed” and “decoded” may be used interchangeably, the terms “pixel” and “sample” may be used interchangeably, the terms “image,” “picture” and “frame” may be used interchangeably. Usually, but not necessarily, the term “reconstructed” is used at the encoder side while “decoded” is used at the decoder side.

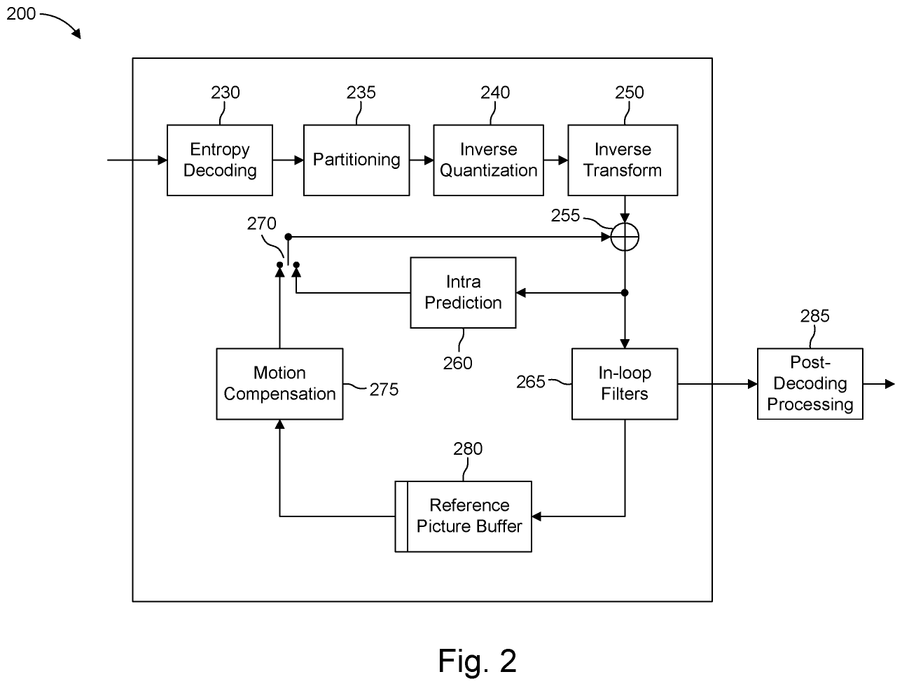

Various methods and other aspects described in this application can be used to modify modules, for example, the intra prediction, entropy coding, and/or decoding modules (160, 260, 145, 230), of an encoder 100 and decoder 200 as shown in FIG. 1 and FIG. 2. Moreover, the present aspects are not limited to VVC or HEVC, and can be applied, for example, to other standards and recommendations, whether pre-existing or future-developed, and extensions of any such standards and recommendations (including VVC and HEVC).

Moreover, the present aspects are not limited to VVC or HEVC, or even to video data, and can be applied to an encoder or decoder adapted to encode, respectively decode, at least one tensor of at least one layer of a neural network that can be used in many technical fields other than video (of course, in such embodiments, some modules like intra prediction module 160 can be optional)

Unless indicated otherwise, or technically precluded, the aspects described in this application can be used individually or in combination.

Various numeric values are used in the present application (for example tensor-reconstruction-modes). The specific values are for example purposes and the aspects described are not limited to these specific values.

FIG. 1 illustrates an encoder 100. Variations of this encoder 100 are contemplated, but the encoder 100 is described below for purposes of clarity without describing all expected variations.

Before being encoded, the sequence may go through pre-encoding processing (101), for example, applying a color transform to the input color picture (e.g., conversion from RGB 4:4:4 to YCbCr 4:2:0) in case of a video sequence, or performing a remapping of the input picture components in order to get a signal distribution more resilient to compression (for instance using a histogram equalization of one of the color components). Also, pre-encoding processing can include binarization as the exemplary binarization detailed above in link with CABAC.

Metadata can be associated with the pre-processing and attached to the bitstream.

In the encoder 100, in case of a video sequence, a picture is encoded by the encoder elements as described below. The picture to be encoded is partitioned (102) and processed in units of, for example, CUs. Each unit is encoded using, for example, either an intra or inter mode. When a unit is encoded in an intra mode, it performs intra prediction (160). In an inter mode, motion estimation (175) and compensation (170) are performed. The encoder decides (105) which one of the intra mode or inter mode to use for encoding the unit, and indicates the intra/inter decision by, for example, a prediction mode flag. Prediction residuals are calculated, for example, by subtracting (110) the predicted block from the original image block.

The prediction residuals are then transformed (125) and quantized (130).

The quantized transform coefficients, as well as motion vectors and other syntax elements, are entropy coded (145) to output a bitstream.

The encoder can skip the transform and apply quantization directly to the non-transformed residual signal. The encoder can bypass both transform and quantization, i.e., the residual is coded directly without the application of the transform or quantization processes.

The encoder decodes an encoded block to provide a reference for further predictions. The quantized transform coefficients are de-quantized (140) and inverse transformed (150) to decode prediction residuals. For instance, in case of a video sequence, combining (155) the decoded prediction residuals and the predicted block, an image block is reconstructed. In-loop filters (165) are applied to the reconstructed picture to perform, for example, deblocking/SAO (Sample Adaptive Offset) filtering to reduce encoding artifacts. The filtered image is stored at a reference picture buffer (180).

FIG. 2 illustrates a block diagram of a decoder 200. In the decoder 200, a bitstream is decoded by the decoder elements as described below. Decoder 200 generally performs a decoding pass almost reciprocal, to the encoding pass as described in FIG. 1. The encoder 100 also generally performs decoding as part of encoding data.

In particular, the input of the decoder 200 includes a bitstream, which can be generated by encoder 100. The bitstream is first entropy decoded (230) to obtain transform coefficients, motion vectors, and other coded information.

In case of a video bitstream, the picture partition information indicates how the picture is partitioned. The decoder may therefore divide (235) the picture according to the decoded picture partitioning information. The transform coefficients are de-quantized (240) and inverse transformed (250) to decode the prediction residuals. Combining (255) the decoded prediction residuals and the predicted block, an image block is reconstructed. The predicted block can be obtained (270) from intra prediction (260) or motion-compensated prediction (i.e., inter prediction) (275). In-loop filters (265) are applied to the reconstructed image. The filtered image is stored at a reference picture buffer (280).

The decoded element (like the picture or the layer weights) can further go through post-decoding processing (285), for example, in case of a decoded image, an inverse color transform (e.g. conversion from YCbCr 4:2:0 to RGB 4:4:4) or an inverse remapping performing the inverse of the remapping process performed in the pre-encoding processing (101). The post-decoding processing can use metadata derived in the pre-encoding processing and signaled in the bitstream.

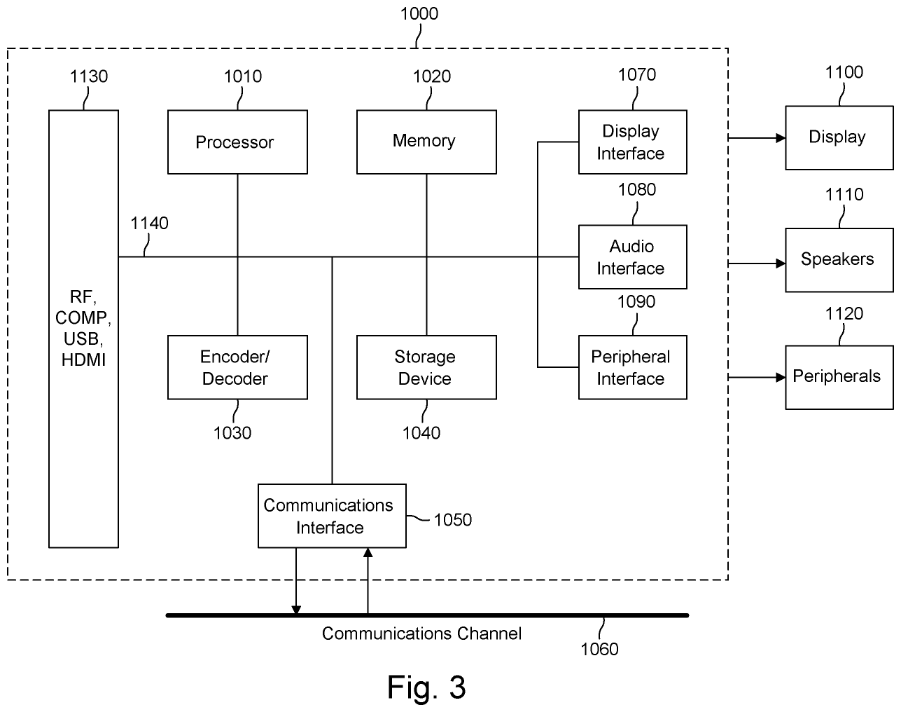

FIG. 3 illustrates a block diagram of an example of a system in which various aspects and embodiments are implemented. System 1000 can be embodied as a device including the various components described below and is configured to perform one or more of the aspects described in this document. Examples of such devices include, but are not limited to, various electronic devices such as personal computers, laptop computers, smartphones, tablet computers, digital multimedia set top boxes, digital television receivers, personal video recording systems, connected home appliances, and servers. Elements of system 1000, singly or in combination, can be embodied in a single integrated circuit (IC), multiple ICs, and/or discrete components. For example, in at least one embodiment, the processing and encoder/decoder elements of system 1000 are distributed across multiple ICs and/or discrete components. In various embodiments, the system 1000 is communicatively coupled to one or more other systems, or other electronic devices, via, for example, a communications bus or through dedicated input and/or output ports. In various embodiments, the system 1000 is configured to implement one or more of the aspects described in this document.

The system 1000 includes at least one processor 1010 configured to execute instructions loaded therein for implementing, for example, the various aspects described in this document. Processor 1010 can include embedded memory, input output interface, and various other circuitries as known in the art. The system 1000 includes at least one memory 1020 (e.g., a volatile memory device, and/or a non-volatile memory device). System 1000 includes a storage device 1040, which can include non-volatile memory and/or volatile memory, including, but not limited to, Electrically Erasable Programmable Read-Only Memory (EEPROM), Read-Only Memory (ROM), Programmable Read-Only Memory (PROM), Random Access Memory (RAM), Dynamic Random-Access Memory (DRAM), Static Random-Access Memory (SRAM), flash, magnetic disk drive, and/or optical disk drive. The storage device 1040 can include an internal storage device, an attached storage device (including detachable and non-detachable storage devices), and/or a network accessible storage device, as non-limiting examples.

System 1000 includes an encoder/decoder module 1030 configured, for example, to process data to provide an encoded or decoded data stream (such a video stream and/or a stream representative of at least one weight of at least one layer of at least one DNN), and the encoder/decoder module 1030 can include its own processor and memory. The encoder/decoder module 1030 represents module(s) that can be included in a device to perform the encoding and/or decoding functions. As is known, a device can include one or both of the encoding and decoding modules. Additionally, encoder/decoder module 1030 can be implemented as a separate element of system 1000 or can be incorporated within processor 1010 as a combination of hardware and software as known to those skilled in the art.

Program code to be loaded onto processor 1010 or encoder/decoder 1030 to perform the various aspects described in this document can be stored in storage device 1040 and subsequently loaded onto memory 1020 for execution by processor 1010. In accordance with various embodiments, one or more of processor 1010, memory 1020, storage device 1040, and encoder/decoder module 1030 can store one or more of various items during the performance of the processes described in this document. Such stored items can include, but are not limited to, the input video, the decoded video or portions of the decoded video, data representative of at least one weight of at least one tensor of at least one layer of the at least one DNN, the bitstream, matrices, variables, and intermediate or final results from the processing of equations, formulas, operations, and operational logic.

In some embodiments, memory inside of the processor 1010 and/or the encoder/decoder module 1030 is used to store instructions and to provide working memory for processing that is needed during encoding or decoding. In other embodiments, however, a memory external to the processing device (for example, the processing device can be either the processor 1010 or the encoder/decoder module 1030) is used for one or more of these functions. The external memory can be the memory 1020 and/or the storage device 1040, for example, a dynamic volatile memory and/or a non-volatile flash memory. In several embodiments, an external non-volatile flash memory is used to store the operating system of, for example, a television. In at least one embodiment, a fast external dynamic volatile memory such as a RAM is used as working memory for coding and decoding operations, such as for MPEG-2 (MPEG refers to the Moving Picture Experts Group, MPEG-2 is also referred to as ISO/IEC 13818, and 13818-1 is also known as H.222, and 13818-2 is also known as H.262), HEVC (HEVC refers to High Efficiency Video Coding, also known as H.265 and MPEG-H Part 2), or VVC (Versatile Video Coding, a new standard being developed by JVET, the Joint Video Experts Team).

The input to the elements of system 1000 can be provided through various input devices as indicated in block 1130. Such input devices include, but are not limited to, (i) a radio frequency (RF) portion that receives an RF signal transmitted, for example, over the air by a broadcaster, (ii) a Component (COMP) input terminal (or a set of COMP input terminals), (iii) a Universal Serial Bus (USB) input terminal, and/or (iv) a High Definition Multimedia Interface (HDMI) input terminal. Other examples, not shown in FIG. 3, include composite video.

In various embodiments, the input devices of block 1130 have associated respective input processing elements as known in the art. For example, the RF portion can be associated with elements suitable for (i) selecting a desired frequency (also referred to as selecting a signal, or band-limiting a signal to a band of frequencies), (ii) down converting the selected signal, (iii) band-limiting again to a narrower band of frequencies to select (for example) a signal frequency band which can be referred to as a channel in certain embodiments, (iv) demodulating the down converted and band-limited signal, (v) performing error correction, and (vi) demultiplexing to select the desired stream of data packets. The RF portion of various embodiments includes one or more elements to perform these functions, for example, frequency selectors, signal selectors, band-limiters, channel selectors, filters, downconverters, demodulators, error correctors, and demultiplexers. The RF portion can include a tuner that performs various of these functions, including, for example, down converting the received signal to a lower frequency (for example, an intermediate frequency or a near-baseband frequency) or to baseband. In one set-top box embodiment, the RF portion and its associated input processing element receives an RF signal transmitted over a wired (for example, cable) medium, and performs frequency selection by filtering, down converting, and filtering again to a desired frequency band. Various embodiments rearrange the order of the above-described (and other) elements, remove some of these elements, and/or add other elements performing similar or different functions. Adding elements can include inserting elements in between existing elements, such as, for example, inserting amplifiers and an analog-to-digital converter. In various embodiments, the RF portion includes an antenna.

Additionally, the USB and/or HDMI terminals can include respective interface processors for connecting system 1000 to other electronic devices across USB and/or HDMI connections. It is to be understood that various aspects of input processing, for example, Reed-Solomon error correction, can be implemented, for example, within a separate input processing IC or within processor 1010, as necessary. Similarly, aspects of USB or HDMI interface processing can be implemented within separate interface ICs or within processor 1010, as necessary. The demodulated, error corrected, and demultiplexed stream is provided to various processing elements, including, for example, processor 1010, and encoder/decoder 1030 operating in combination with the memory and storage elements to process the data stream as necessary for presentation on an output device.

Various elements of system 1000 can be provided within an integrated housing, Within the integrated housing, the various elements can be interconnected and transmit data therebetween using suitable connection arrangement 1140, for example, an internal bus as known in the art, including the Inter-IC (I2C) bus, wiring, and printed circuit boards.

The system 1000 includes communication interface 1050 that enables communication with other devices via communication channel 1060. The communication interface 1050 can include, but is not limited to, a transceiver configured to transmit and to receive data over communication channel 1060. The communication interface 1050 can include, but is not limited to, a modem or network card and the communication channel 1060 can be implemented, for example, within a wired and/or a wireless medium.

Data is streamed, or otherwise provided, to the system 1000, in various embodiments, using a wireless network such as a Wi-Fi network, for example IEEE 802.11 (IEEE refers to the Institute of Electrical and Electronics Engineers). The Wi-Fi signal of these embodiments is received over the communications channel 1060 and the communications interface 1050 which are adapted for Wi-Fi communications. The communications channel 1060 of these embodiments is typically connected to an access point or router that provides access to external networks including the Internet for allowing streaming applications and other over-the-top communications. Other embodiments provide streamed data to the system 1000 using a set-top box that delivers the data over the HDMI connection of the input block 1130. Still other embodiments provide streamed data to the system 1000 using the RF connection of the input block 1130. As indicated above, various embodiments provide data in a non-streaming manner. Additionally, various embodiments use wireless networks other than Wi-Fi, for example a cellular network or a Bluetooth network.

The system 1000 can provide an output signal to various output devices, including a display 1100, speakers 1110, and other peripheral devices 1120. The display 1100 of various embodiments includes one or more of, for example, a touchscreen display, an organic light-emitting diode (OLED) display, a curved display, and/or a foldable display. The display 1100 can be for a television, a tablet, a laptop, a cell phone (mobile phone), or another device. The display 1100 can also be integrated with other components (for example, as in a smart phone), or separate (for example, an external monitor for a laptop). The other peripheral devices 1120 include, in various examples of embodiments, one or more of a stand-alone digital video disc (or digital versatile disc) (DVR, for both terms), a disk player, a stereo system, and/or a lighting system. Various embodiments use one or more peripheral devices 1120 that provide a function based on the output of the system 1000. For example, a disk player performs the function of playing the output of the system 1000.

In various embodiments, control signals are communicated between the system 1000 and the display 1100, speakers 1110, or other peripheral devices 1120 using signaling such as AV. Link, Consumer Electronics Control (CEC), or other communications protocols that enable device-to-device control with or without user intervention. The output devices can be communicatively coupled to system 1000 via dedicated connections through respective interfaces 1070, 1080, and 1090. Alternatively, the output devices can be connected to system 1000 using the communications channel 1060 via the communications interface 1050. The display 1100 and speakers 1110 can be integrated in a single unit with the other components of system 1000 in an electronic device such as, for example, a television. In various embodiments, the display interface 1070 includes a display driver, such as, for example, a timing controller (T Con) chip.

The display 1100 and speaker 1110 can alternatively be separate from one or more of the other components, for example, if the RF portion of input 1130 is part of a separate set-top box. In various embodiments in which the display 1100 and speakers 1110 are external components, the output signal can be provided via dedicated output connections, including, for example, HDMI ports, USB ports, or COMP outputs.

The embodiments can be carried out by computer software implemented by the processor 1010 or by hardware, or by a combination of hardware and software. As a non-limiting example, the embodiments can be implemented by one or more integrated circuits. The memory 1020 can be of any type appropriate to the technical environment and can be implemented using any appropriate data storage technology, such as optical memory devices, magnetic memory devices, semiconductor-based memory devices, fixed memory, and removable memory, as non-limiting examples. The processor 1010 can be of any type appropriate to the technical environment, and can encompass one or more of microprocessors, general purpose computers, special purpose computers, and processors based on a multi-core architecture, as non-limiting examples.

Various implementations involve decoding. “Decoding”, as used in this application, can encompass all or part of the processes performed, for example, on a received encoded sequence in order to produce a final output suitable for display. In various embodiments, such processes include one or more of the processes typically performed by a decoder, for example, entropy decoding, inverse quantization, inverse transformation, and differential decoding. In various embodiments, such processes also, or alternatively, include processes performed by a decoder of various implementations described in this application.

As further examples, in one embodiment “decoding” refers only to entropy decoding, in another embodiment “decoding” refers only to differential decoding, and in another embodiment “decoding” refers to a combination of entropy decoding and differential decoding. Whether the phrase “decoding process” is intended to refer specifically to a subset of operations or generally to the broader decoding process will be clear based on the context of the specific descriptions and is believed to be well understood by those skilled in the art.

Various implementations involve encoding. In an analogous way to the above discussion about “decoding”, “encoding” as used in this application can encompass all or part of the processes performed, for example, on an input sequence in order to produce an encoded bitstream. In various embodiments, such processes include one or more of the processes typically performed by an encoder, for example, partitioning, differential encoding, transformation, quantization, and entropy encoding. In various embodiments, such processes also, or alternatively, include processes performed by an encoder of various implementations described in this application.

As further examples, in one embodiment “encoding” refers only to entropy encoding, in another embodiment “encoding” refers only to differential encoding, and in another embodiment “encoding” refers to a combination of differential encoding and entropy encoding. Whether the phrase “encoding process” is intended to refer specifically to a subset of operations or generally to the broader encoding process will be clear based on the context of the specific descriptions and is believed to be well understood by those skilled in the art.

Note that the syntax elements as used herein, are descriptive terms. As such, they do not preclude the use of other syntax element names.

When a figure is presented as a flow diagram, it should be understood that it also provides a block diagram of a corresponding apparatus. Similarly, when a figure is presented as a block diagram, it should be understood that it also provides a flow diagram of a corresponding method/process.

Various embodiments refer to parametric models or rate distortion optimization. In particular, during the encoding process, the balance or trade-off between the rate and distortion is usually considered, often given the constraints of computational complexity. It can be measured through a Rate Distortion Optimization (RDO) metric, or through Least Mean Square (LMS), Mean of Absolute Errors (MAE), or other such measurements. The rate distortion optimization is usually formulated as minimizing a rate distortion function, which is a weighted sum of the rate and of the distortion. There are different approaches to solve the rate distortion optimization problem. For example, the approaches may be based on an extensive testing of all encoding options, including all considered modes or coding parameters values, with a complete evaluation of their coding cost and related distortion of the reconstructed signal after coding and decoding. Faster approaches may also be used, to save encoding complexity, in particular with computation of an approximated distortion based on the prediction or the prediction residual signal, not the reconstructed one. Mix of these two approaches can also be used, such as by using an approximated distortion for only some of the possible encoding options, and a complete distortion for other encoding options. Other approaches only evaluate a subset of the possible encoding options. More generally, many approaches employ any of a variety of techniques to perform the optimization, but the optimization is not necessarily a complete evaluation of both the coding cost and related distortion.

The implementations and aspects described herein can be implemented in, for example, a method or a process, an apparatus, a software program, a data stream, or a signal. Even if only discussed in the context of a single form of implementation (for example, discussed only as a method), the implementation of features discussed can also be implemented in other forms (for example, an apparatus or program). An apparatus can be implemented in, for example, appropriate hardware, software, and firmware. The methods can be implemented in, for example, a processor, which refers to processing devices in general, including, for example, a computer, a microprocessor, an integrated circuit, or a programmable logic device. Processors also include communication devices, such as, for example, computers, cell phones, portable/personal digital assistants (“PDAs”), and other devices that facilitate communication of information between end-users.

Reference to “one embodiment” or “an embodiment” or “one implementation” or “an implementation”, as well as other variations thereof, means that a particular feature, structure, characteristic, and so forth described in connection with the embodiment is included in at least one embodiment. Thus, the appearances of the phrase “in one embodiment” or “in an embodiment” or “in one implementation” or “in an implementation”, as well any other variations, appearing in various places throughout this application are not necessarily all referring to the same embodiment.

Additionally, this application may refer to “determining” various pieces of information. Determining the information can include one or more of, for example, estimating the information, calculating the information, predicting the information, or retrieving the information from memory.

Further, this application may refer to “accessing” various pieces of information. Accessing the information can include one or more of, for example, receiving the information, retrieving the information (for example, from memory), storing the information, moving the information, copying the information, calculating the information, determining the information, predicting the information, or estimating the information.

Additionally, this application may refer to “receiving” various pieces of information. Receiving is, as with “accessing”, intended to be a broad term. Receiving the information can include one or more of, for example, accessing the information, or retrieving the information (for example, from memory). Further, “receiving” is typically involved, in one way or another, during operations such as, for example, storing the information, processing the information, transmitting the information, moving the information, copying the information, erasing the information, calculating the information, determining the information, predicting the information, or estimating the information.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as is clear to one of ordinary skill in this and related arts, for as many items as are listed.

Also, as used herein, the word “signal” refers to, among other things, indicating something to a corresponding decoder. For example, in certain embodiments the encoder signals at least one of a plurality of transforms, coding modes or flags. In this way, in an embodiment the same parameter is used at both the encoder side and the decoder side. Thus, for example, an encoder can transmit (explicit signaling) a particular parameter to the decoder so that the decoder can use the same particular parameter. Conversely, if the decoder already has the particular parameter as well as others, then signaling can be used without transmitting (implicit signaling) to simply allow the decoder to know and select the particular parameter. By avoiding transmission of any actual functions, a bit savings is realized in various embodiments. It is to be appreciated that signaling can be accomplished in a variety of ways. For example, one or more syntax elements, flags, and so forth are used to signal information to a corresponding decoder in various embodiments. While the preceding relates to the verb form of the word “signal”, the word “signal” can also be used herein as a noun.

As will be evident to one of ordinary skill in the art, implementations can produce a variety of signals formatted to carry information that can be, for example, stored or transmitted. The information can include, for example, instructions for performing a method, or data produced by one of the described implementations. For example, a signal can be formatted to carry the bitstream of a described embodiment. Such a signal can be formatted, for example, as an electromagnetic wave (for example, using a radio frequency portion of spectrum) or as a baseband signal. The formatting can include, for example, encoding a data stream and modulating a carrier with the encoded data stream. The information that the signal carries can be, for example, analog or digital information. The signal can be transmitted over a variety of different wired or wireless links, as is known. The signal can be stored on a processor-readable medium.

We describe a number of embodiments. Features of these embodiments can be provided alone or in any combination, across various claim categories and types. Further, embodiments can include one or more of the following features, devices, or aspects, alone or in any combination, across various claim categories and types:
A process or device to perform encoding and decoding with deep neural network compression of a pre-trained deep neural network.
A process or device to perform encoding and decoding of at least one layer of a pre-trained deep neural network, to implement deep neural network compression.
A process or device to perform encoding and decoding with inserted information in a bitstream representative of parameters to implement deep neural network compression of a pre-trained deep neural network comprising one or more layers.
A process or device to perform encoding and decoding with inserted information in a bitstream representative of parameters to implement deep neural network compression of a deep neural network.
A bitstream or signal that includes one or more of the described syntax elements, or variations thereof.
A bitstream or signal that includes syntax conveying information generated according to any of the embodiments described.
Creating and/or transmitting and/or receiving and/or decoding according to any of the embodiments described.
A method, process, apparatus, medium storing instructions, medium storing data, or signal according to any of the embodiments described.
Inserting in the signaling syntax elements that enable the decoder to determine coding mode in a manner corresponding to that used by an encoder.
Creating and/or transmitting and/or receiving and/or decoding a bitstream or signal that includes one or more of the described syntax elements, or variations thereof.
A TV, set-top box, cell phone, tablet, or other electronic device that performs transform method(s) according to any of the embodiments described.
A TV, set-top box, cell phone, tablet, or other electronic device that performs transform method(s) determination according to any of the embodiments described, and that displays (e.g. using a monitor, screen, or other type of display) a resulting image.
A TV, set-top box, cell phone, tablet, or other electronic device that selects, bandlimits, or tunes (e.g. using a tuner) a channel to receive a signal including an encoded image, and performs transform method(s) according to any of the embodiments described.
A TV, set-top box, cell phone, tablet, or other electronic device that receives (e.g. using an antenna) a signal over the air that includes an encoded image, and performs transform method(s).

1-25. (canceled)

26. A method comprising:
responsive to a determination that a first tensor of a layer of a Deep Neural Network is decomposed into a second tensor and a third tensor whose parameters are encoded in a bitstream, decoding from the bitstream one or more sizes corresponding to at least one or more of the second tensor and the third tensor; and
decoding the second tensor and the third tensor based on the one or more decoded sizes to obtain the decoded second tensor and a decoded third tensor.

27. The method of claim 26, further comprising decoding from the bitstream a decomposition rank of a tensor decomposition of the first tensor decomposed into the second tensor and the third tensor.

28. The method of claim 26, further comprising:
deriving one or more sizes of one or more of the second tensor or the third tensor based on the one or more decoded sizes; and
decoding one or more of the second tensor and the third tensor based on the one or more derived sizes.

29. The method of claim 26, further comprising reconstructing the first tensor based on the decoded second tensor and the decoded third tensor.

30. The method of claim 26, further comprising:
storing one or more of the decoded second tensor and the decoded third tensor in a decoded tensor buffer.

31. The method of claim 30, further comprising determining if one or more of the decoded second tensor and the decoded third tensor is in the decoded tensor buffer by looking for a tensor associated with an identifier, the identifier comprising a same layer as the one or more of the decoded second tensor and the decoded third tensor.

32. The method of claim 26, wherein the bitstream includes additional parameters associated with the first tensor.

33. An apparatus comprising one or more processors, the one or more processors configured to:
responsive to a determination that a first tensor of a layer of a Deep Neural Network is decomposed into a second tensor and a third tensor whose parameters are encoded in a bitstream, decode from the bitstream one or more sizes corresponding to at least one or more of the second tensor and the third tensor; and
decode the second tensor and the third tensor based on the one or more decoded sizes to obtain the decoded second tensor and a decoded third tensor.

34. The apparatus of claim 33, wherein the one or more processors are further configured to:
derive one or more sizes of one or more of the second tensor or the third tensor based on the one or more decoded sizes; and
decode one or more of the second tensor and the third tensor based on the one or more derived sizes.

35. The apparatus of claim 33, wherein the one or more processors are further configured to reconstruct the first tensor based on the decoded second tensor and the decoded third tensor.

36. The apparatus of claim 33, wherein the one or more processors are further configured to:
store one or more of the decoded second tensor and the decoded third tensor in a decoded tensor buffer; and
determine if one or more of the decoded second tensor and the decoded third tensor is in the decoded tensor buffer by looking for a tensor associated with an identifier, the identifier comprising a same layer as the one or more of the decoded second tensor and the decoded third tensor.

37. The apparatus of claim 33, wherein the bitstream includes additional parameters associated with the first tensor.

38. A method comprising:
decomposing a first tensor of a layer of a Deep Neural Network into a second tensor and a third tensor;
deriving one or more sizes corresponding to at least one or more of the second tensor and the third tensor; and
encoding the second tensor and the third tensor in a bitstream based on the determined one or more sizes, wherein the one or more sizes corresponding to at least one or more of the second tensor and the third tensor are encoded in the bitstream.

39. The method of claim 13, further comprising encoding into the bitstream a decomposition rank of a tensor decomposition of the first tensor decomposed into the second tensor and the third tensor.

40. The method of claim 38, further comprising storing one or more of the second tensor and the decomposed third tensor in a tensor buffer.

41. The method of claim 38, further comprising transmitting the bitstream to a decoder.

42. An apparatus comprising one or more processors, the one or more processors configured to:
decompose a first tensor of a layer of a Deep Neural Network into a second tensor and a third tensor;
derive one or more sizes corresponding to at least one or more of the second tensor and the third tensor; and
encode the second tensor and the third tensor in a bitstream based on the determined one or more sizes, wherein the one or more sizes corresponding to at least one or more of the second tensor and the third tensor are encoded in the bitstream.

43. The apparatus of claim 42, wherein the one or more processors are further configured to encode into the bitstream a decomposition rank of a tensor decomposition of the first tensor decomposed into the second tensor and the third tensor.

44. The apparatus of claim 42, wherein the one or more processors are further configured to store one or more of the second tensor and the decomposed third tensor in a tensor buffer.

45. The apparatus of claim 42, wherein the one or more processors are further configured to transmit the bitstream to a decoder.
